(19) United States
(12) Patent Application Publication
(10) Pub. No.: US 2024/0062066 A1
(43) Pub. Date: Feb. 22, 2024

(54) INFORMATION PROCESSING APPARATUS AND MACHINE LEARNING APPARATUS

(71) Applicant: EBARA CORPORATION, Tokyo (JP)

(72) Inventors: CHING WEI HUANG, Tokyo (JP); HIROFUMI OTAKI, Tokyo (JP); TAKAMASA NAKAMURA, Tokyo (JP)

(73) Assignee: EBARA CORPORATION, Tokyo (JP)

(21) Appl. No.: 18/451,109

(22) Filed: Aug. 17, 2023

(30) Foreign Application Priority Data
Aug. 17, 2022 (JP) 2022-130013

(51) Int. Cl. G06N 3/084

(52) U.S. Cl. CPC G06N 3/084; H01L 21/67253

(57) ABSTRACT

An information processing apparatus includes: an information acquisition part, acquiring recipe information indicating processing content of polishing processing and finishing processing, and transfer time information indicating a transfer time required for each transfer processing; and a schedule creation part, based on the recipe information and the transfer time information, creating a substrate processing schedule by determining a start timing of each processing so that a final processing end time during which a final substrate after the finishing processing is carried out to a substrate carry-out position is shortest.

### CROSS-REFERENCE TO RELATED APPLICATIONS

This application claims the priority benefit of Japan Application No. 2022-130013, filed on Aug. 17, 2022. The entirety of the above-mentioned patent application is hereby incorporated by reference herein and made a part of this specification.

### BACKGROUND

### Technical Field

The disclosure relates to an information processing apparatus, a machine learning apparatus, an information processing method, and a machine learning method.

### Related Art

A substrate processing apparatus that performs chemical mechanical polishing (CMP) processing is known as one of substrate processing apparatuses that perform various processings on a substrate such as a semiconductor wafer. Such a substrate processing apparatus includes, for example, a polishing unit that performs polishing processing on the substrate, a finishing unit that performs finishing processing (for example, cleaning processing or drying processing) on the substrate after polishing processing, and a transfer unit that performs transfer processing for transferring the substrate between each unit. The substrate processing apparatus is configured to sequentially operate each unit to thereby execute a series of processings (see, for example, Japanese Patent Laid-open No. 2004-265906).

To improve processing efficiency, the substrate processing apparatus is configured to include a plurality of polishing units, a plurality of finishing units, and a plurality of transfer units. Hence, in the substrate processing apparatus, in the case of sequentially operating each unit for a predetermined number of substrates to be processed, it is desired to create a substrate processing schedule for each processing by appropriately determining an operation order or operation timing of each unit, so that the time required to complete each processing for all the substrates is shortest.

### SUMMARY

An information processing apparatus according to one aspect of the disclosure creates a substrate processing schedule for sequentially performing each processing on a predetermined number of substrates in a substrate processing apparatus. The substrate processing apparatus includes a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate. The information processing apparatus includes: an information acquisition part, acquiring recipe information and transfer time information, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position; and a schedule creation part, based on the recipe information and the transfer time information acquired by the information acquisition part, creating the substrate processing schedule by determining a start timing of each of the processing so that a final processing end time during which a last one of the substrate after the finishing processing is carried out to the substrate carry-out position is shortest.

### BRIEF DESCRIPTION OF THE DRAWINGS

FIG. 1 is an overall configuration diagram illustrating an example of a substrate processing system 1.

FIG. 2 is a schematic plan view illustrating an example of a substrate processing apparatus 2.

FIG. 3 is a perspective view illustrating an example of a first polishing unit 22A and a second polishing unit 22B.

FIG. 4 is a perspective view illustrating an example of a first finishing unit 23A that performs roll sponge cleaning processing.

FIG. 5 is a perspective view illustrating an example of a second finishing unit 23B that performs pen sponge cleaning processing.

FIG. 6 is a perspective view illustrating an example of a third finishing unit 23C that performs drying processing.

FIG. 7 is a block diagram illustrating an example of the substrate processing apparatus 2.

FIG. 8 is a hardware configuration diagram illustrating an example of a computer 900.

FIG. 9 is a block diagram illustrating an example of an information processing apparatus 3A according to a first embodiment.

FIG. 10 is a functional explanatory view illustrating an example of the information processing apparatus 3A according to the first embodiment.

FIG. 11 illustrates an example of a substrate processing schedule 13A before mathematical optimization.

FIG. 12 illustrates an example of a post-polishing finishing start time TW and a range TWR thereof.

FIG. 13 illustrates an example of a substrate processing schedule 13B after mathematical optimization.

FIG. 14 illustrates an example of an evaluation index 14 with respect to the substrate processing schedules 13A and 13B.

FIG. 15 is a flowchart illustrating an example of an information processing method performed by the information processing apparatus 3A according to the first embodiment.

FIG. 16 is a block diagram illustrating an example of an information processing apparatus 3B according to a second embodiment.

FIG. 17 is a functional explanatory view illustrating an example of the information processing apparatus 3B according to the second embodiment.

FIG. 18 illustrates an example of learning data 15A and a learning model 16A according to the second embodiment.

FIG. 19 is a flowchart illustrating an example of a machine learning method performed by a machine learning apparatus 5A.

FIG. 20 is a flowchart illustrating an example of an information processing method performed by the information processing apparatus 3B according to the second embodiment.

FIG. 21 is a block diagram illustrating an example of an information processing apparatus 3C according to a third embodiment.

FIG. 22 is a functional explanatory view illustrating an example of the information processing apparatus 3C according to the third embodiment.

FIG. 23 illustrates an example of learning data 15B and a learning model 16B according to the third embodiment.

FIG. 24 is a flowchart illustrating an example of an information processing method performed by the information processing apparatus 3C according to the third embodiment.

### DESCRIPTION OF THE EMBODIMENTS

The disclosure provides an information processing apparatus, a machine learning apparatus, an information processing method, and a machine learning method that make it possible to appropriately create a substrate processing schedule.

An information processing apparatus according to one aspect of the disclosure creates a substrate processing schedule for sequentially performing each processing on a predetermined number of substrates in a substrate processing apparatus. The substrate processing apparatus includes a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate. The information processing apparatus includes: an information acquisition part, acquiring recipe information and transfer time information, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position; and a schedule creation part, based on the recipe information and the transfer time information acquired by the information acquisition part, creating the substrate processing schedule by determining a start timing of each of the processing so that a final processing end time during which a last one of the substrate after the finishing processing is carried out to the substrate carry-out position is shortest.

According to the information processing apparatus according to one aspect of the disclosure, based on the recipe information and the transfer time information, the schedule creation part creates the substrate processing schedule by determining the start timing of each processing so that the final processing end time is shortest. Accordingly, since the substrate processing schedule reflects the processing content of each processing or the time required for each processing, the substrate processing schedule can be appropriately created.

Problems, configurations, and effects other than those described above will be clear from the following description of the embodiments.

Embodiments for implementing the disclosure will be described below with reference to the drawings. In the following, a scope necessary for description for achieving an object of the disclosure is schematically indicated, a scope necessary for description of a part of the disclosure falling within that scope is mainly described, and parts of the disclosure of which description is omitted are performed by known techniques.

### First Embodiment

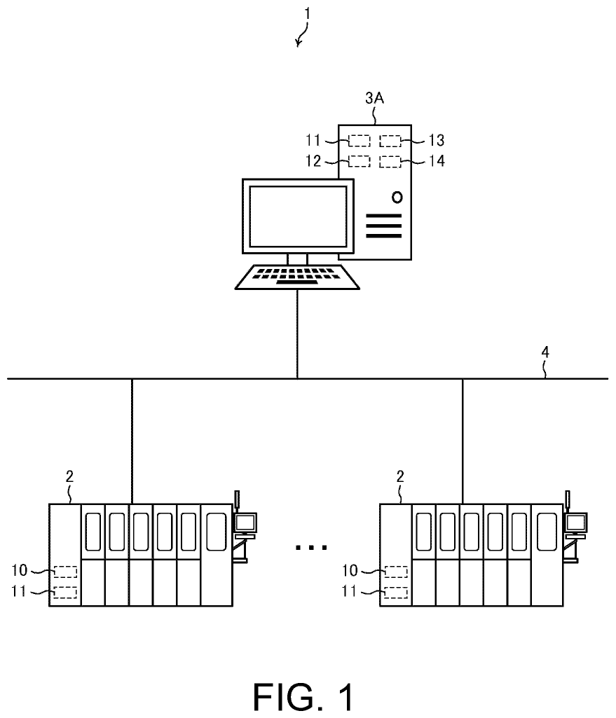

FIG. 1 is an overall configuration diagram illustrating an example of a substrate processing system 1. The substrate processing system 1 according to the present embodiment includes, as its main configuration, a substrate processing apparatus 2 and an information processing apparatus 3A, which are connected to a wired or wireless network 4 and configured to be able to mutually transmit and receive various data. The number of the substrate processing apparatus 2 and the information processing apparatus 3A or the connection configuration of the network 4 is not limited to the example of FIG. 1, and may be changed as appropriate.

The substrate processing apparatus 2 includes a plurality of processing units (details will be described later) that perform various processings on a substrate (hereinafter referred to as “wafer”) W such as a semiconductor wafer. By operating each processing unit, the substrate processing apparatus 2 performs chemical mechanical polishing processing (hereinafter referred to as “polishing processing”), finishing processing, transfer processing, and the like on the wafer W. At that time, the substrate processing apparatus 2 controls an operation of each processing unit with reference to apparatus setting information 10 and substrate recipe information 11, in which the apparatus setting information 10 contains a plurality of apparatus parameters respectively set for each processing unit, and the substrate recipe information 11 defines an operation in the polishing processing or the finishing processing.

The information processing apparatus 3A is a terminal apparatus used by a user, and is composed of a stationary or portable apparatus. The information processing apparatus 3A, for example, receives various input operations via a display screen of an application program, a web browser or the like, and displays various information via the display screen.

The information processing apparatus 3A is an apparatus that supports simulation or production plan formulation during automatic operation of the substrate processing apparatus 2 in the following way. That is, based on the substrate recipe information 11, or transfer time information 12 indicating the time required for the transfer processing, or the like, the information processing apparatus 3A creates a substrate processing schedule 13 for sequentially performing each processing on a predetermined number of wafers W in the substrate processing apparatus 2, or calculates an evaluation index 14 of the substrate processing schedule 13. The information processing apparatus 3A may be composed of a server type or cloud type apparatus. In that case, the information processing apparatus 3A may be operated in cooperation with a user terminal apparatus (not illustrated) on the client side.

(Substrate Processing Apparatus)

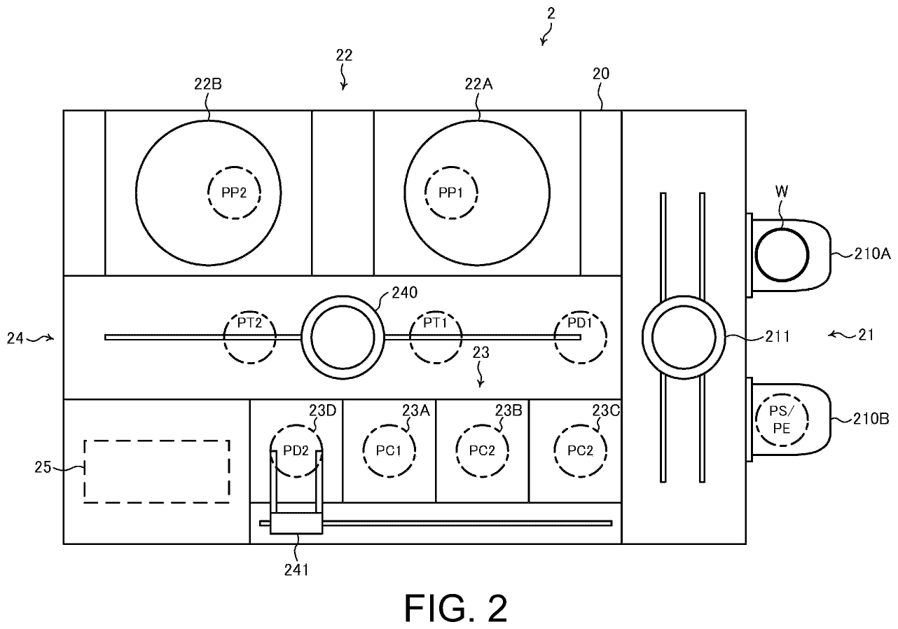

FIG. 2 is a schematic plan view illustrating an example of the substrate processing apparatus 2. The substrate processing apparatus 2 is configured to include, inside a housing 20 having a substantially rectangular shape in plan view, a loading/unloading part 21, a polishing part 22, a finishing part 23, a substrate transfer part 24 and a control unit 25.

(Loading/Unloading Part)

The loading/unloading part 21 includes: a first front loading part 210A and a second front loading part 210B, on which is placed a wafer cassette (such as a front opening unified pod (FOUP)) capable of storing a large number of wafers W in an up-down direction; and a carry-in/carry-out robot 211, as a transfer unit movable along a storage direction (up-down direction) of the wafer W stored in the wafer cassette and a direction (lateral direction of the housing 20) in which the first front loading part 210A and the second front loading part 210B are arranged side by side.

The carry-in/carry-out robot 211 is configured to be accessible to a substrate carry-in position PS, a first substrate delivery position PD1, the finishing part 23 (specifically, finishing unit 23C in a most downstream process described later), and a substrate carry-out position PE. The carry-in/carry-out robot 211 includes upper and lower hands (not illustrated) for delivering the wafer W. The lower hand is used when delivering the wafer W before processing, and the upper hand is used when delivering the wafer W after processing.

The substrate carry-in position PS and the substrate carry-out position PE are positions of the wafer cassette placed on each of the first front loading part 210A and the second front loading part 210B. The carry-in/carry-out robot 211 performs, as the transfer processing for the wafer W, carry-in processing for carrying the wafer W from the wafer cassette as the substrate carry-in position PS into the first substrate delivery position PD1, and carry-out processing for carrying out the wafer W after finishing processing from the finishing part 23 to the wafer cassette as the substrate carry-out position PE. The substrate carry-in position PS and the substrate carry-out position PE may be the same or different positions.

(Polishing Part)

The polishing part 22 includes a plurality of (two in the present embodiment) polishing units 22A and 22B each performing polishing processing on the wafer W. In the present embodiment, the first polishing unit 22A and the second polishing unit 22B are arranged side by side along a longitudinal direction of the housing 20 and perform the polishing processing in parallel.

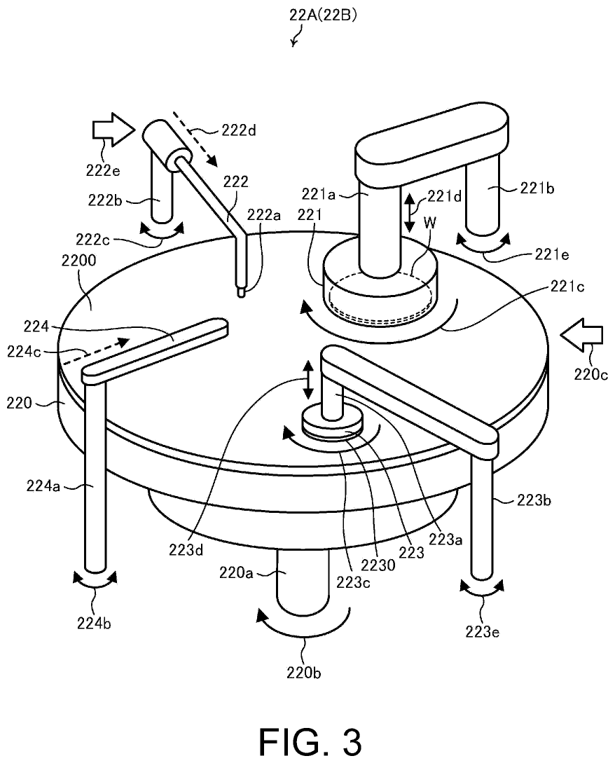

FIG. 3 is a perspective view illustrating an example of the first polishing unit 22A and the second polishing unit 22B. In the present embodiment, a description is given assuming that the first polishing unit 22A and the second polishing unit 22B have basic configurations or functions in common.

Each of the first polishing unit 22A and the second polishing unit 22B includes: a polishing table 220, rotatably supporting a polishing pad 2200 having a polishing surface; a top ring (substrate holder) 221, for rotatably holding the wafer W and polishing while pressing the wafer W against the polishing pad 2200 on the polishing table 220; a polishing fluid supply 222, supplying a polishing fluid to the polishing pad 2200; a dresser 223, rotatably supporting a dresser disk 2230 and bringing the dresser disk 2230 into contact with the polishing surface of the polishing pad 2200 to dress the polishing pad 2200; and an atomizer 224, spraying a cleaning fluid onto the polishing pad 2200.

The polishing table 220 includes: a rotational movement mechanism 220b, supported by a polishing table shaft 220a and driving the polishing table 220 to rotate about its axis; and a temperature control mechanism 220c, adjusting a surface temperature of the polishing pad 2200.

The top ring 221 includes: a rotational movement mechanism 221c, supported by a top ring shaft 221a that is movable in the up-down direction and driving the top ring 221 to rotate about its axis; a vertical movement mechanism 221d, moving the top ring 221 in the up-down direction; and a swing movement mechanism 221e, turning (swinging) and moving the top ring 221 about a support shaft 221b as a turning center. The rotational movement mechanism 221c, the vertical movement mechanism 221d and the swing movement mechanism 221e function as a substrate movement mechanism that moves relative positions of the polishing pad 2200 and a surface to be polished of the wafer W.

The polishing fluid supply 222 includes: a polishing fluid supply nozzle 222a, supplying a polishing fluid to the polishing surface of the polishing pad 2200; a swing movement mechanism 222c, supported by a support shaft 222b and turning and moving the polishing fluid supply nozzle 222a about the support shaft 222b as a turning center; a flow controller 222d, adjusting a flow rate of the polishing fluid; and a temperature control mechanism 222e, adjusting a temperature of the polishing fluid. The polishing fluid is a polishing liquid (slurry) or pure water, and may further contain a chemical liquid, or may be a polishing liquid to which a dispersant is added.

The dresser 223 includes: a rotational movement mechanism 223c, supported by a dresser shaft 223a that is movable in the up-down direction and driving the dresser 223 to rotate about its axis; a vertical movement mechanism 223d, moving the dresser 223 in the up-down direction; and a swing movement mechanism 223e, turning and moving the dresser 223 about a support shaft 223b as a turning center.

The atomizer 224 includes: a swing movement mechanism 224b, supported by a support shaft 224a and turning and moving the atomizer 224 about the support shaft 224a as a turning center; and a flow controller 224c, adjusting a flow rate of the cleaning fluid. The cleaning fluid is a mixed fluid of a liquid (for example, pure water) and a gas (for example, nitrogen gas), or a liquid (for example, pure water).

The wafer W is sucked and held by a lower surface of the top ring 221, moved to predetermined polishing positions PP1 and PP2 on the polishing table 220, and then polished by being pressed by the top ring 221 against the polishing surface of the polishing pad 2200 supplied with the polishing fluid from the polishing fluid supply nozzle 222a.

(Finishing Part)

The finishing part 23 includes: a plurality of (three in the present embodiment) finishing units 23A to 23C, each performing finishing processing on the wafer W; and a wafer station 23D where the wafer W after polishing processing can be put on standby. The first to third finishing units 23A to 23C and the wafer station 23D are arranged side by side along the longitudinal direction of the housing 20, and the first to third finishing units 23A to 23C perform the finishing processing in the order (order of finishing processes) of their arrangement.

In the present embodiment, the first finishing unit 23A performs, as the finishing processing in a most upstream process, roll sponge cleaning processing for cleaning the wafer W after polishing processing by using a roll sponge 2300. The second finishing unit 23B performs pen sponge cleaning processing for cleaning the wafer W after roll sponge cleaning processing by using a pen sponge 2301. The third finishing unit 23C performs, as the finishing processing in the most downstream process, drying processing for drying the wafer W after pen sponge cleaning processing. The wafer station 23D holds the wafer W after polishing processing delivered from a polishing processing transporter 240 (details will be described later), and performs standby processing for putting the wafer W after polishing processing on standby until the same is delivered to a finishing processing transporter 241 (details will be described later). The finishing processing may, for example, be started from the pen sponge cleaning processing and may omit the roll sponge cleaning processing.

The finishing part 23 may include, in place of or in addition to any of the first finishing unit 23A and the second finishing unit 23B, a finishing unit (not illustrated) that performs buff cleaning processing for cleaning the wafer W by using a buff, or may omit any of the first finishing unit 23A and the second finishing unit 23B. In the present embodiment, the first to third finishing units 23A to 23C are described as holding (horizontally holding) the wafer W in a horizontally placed state. However, the wafer W may be vertically or obliquely held.

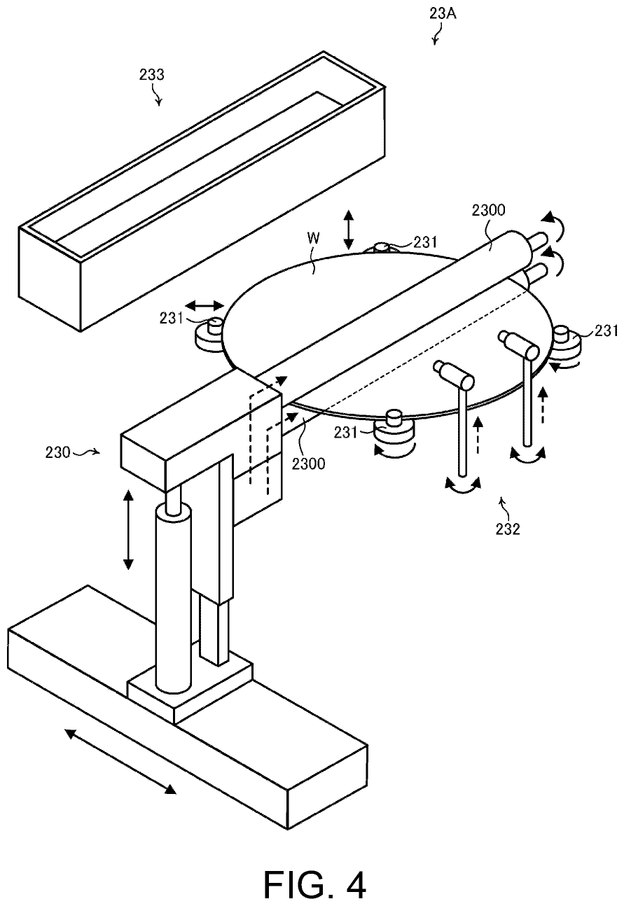

FIG. 4 is a perspective view illustrating an example of the first finishing unit 23A that performs roll sponge cleaning processing. The first finishing unit 23A includes: a substrate holder 231, holding the wafer W; a cleaning fluid supply 232, supplying a substrate cleaning fluid to the wafer W; a substrate cleaning part 230, rotatably supporting the roll sponge 2300 and bringing the roll sponge 2300 into contact with the wafer W to clean the wafer W; and a cleaning tool cleaning part 233, subjecting the roll sponge 2300 to cleaning (self-cleaning) with a cleaning tool cleaning fluid. The substrate cleaning fluid may be either pure water (rinsing liquid) or chemical solution, or may be a liquid, or may be a two-fluid mixture of a liquid and a gas, or may contain a solid such as dry ice. The cleaning tool cleaning fluid may be either pure water (rinsing liquid) or chemical solution.

In the roll sponge cleaning processing performed by the first finishing unit 23A, the wafer W is rotated while being held in a first finishing position PC1 by the substrate holder 231. Then, with the substrate cleaning fluid being supplied from the cleaning fluid supply 232 to a surface to be cleaned of the wafer W, the roll sponge 2300 rotated about its axis by the substrate cleaning part 230 is brought into sliding contact with the surface to be cleaned of the wafer W, thereby cleaning the wafer W.

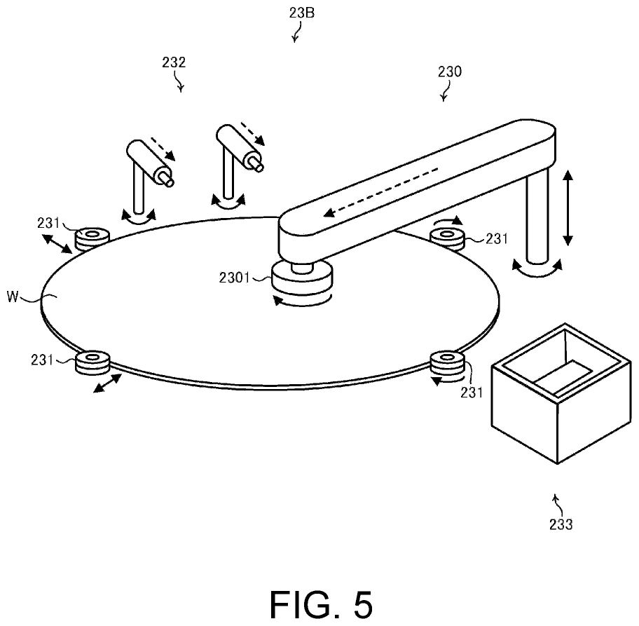

FIG. 5 is a perspective view illustrating an example of the second finishing unit 23B that performs pen sponge cleaning processing. The second finishing unit 23B includes: the substrate holder 231, holding the wafer W; the cleaning fluid supply 232, supplying the substrate cleaning fluid to the wafer W; the substrate cleaning part 230, rotatably supporting the pen sponge 2301 and bringing the pen sponge 2301 into contact with the wafer W to clean the wafer W; and the cleaning tool cleaning part 233, subjecting the pen sponge 2301 to cleaning (self-cleaning) with the cleaning tool cleaning fluid.

In the pen sponge cleaning processing performed by the second finishing unit 23B, the wafer W is rotated while being held in a second finishing position PC2 by the substrate holder 231. Then, with the substrate cleaning fluid being supplied from the cleaning fluid supply 232 to the surface to be cleaned of the wafer W, the pen sponge 2301 rotated about its axis by the substrate cleaning part 230 is brought into sliding contact with the surface to be cleaned of the wafer W, thereby cleaning the wafer W.

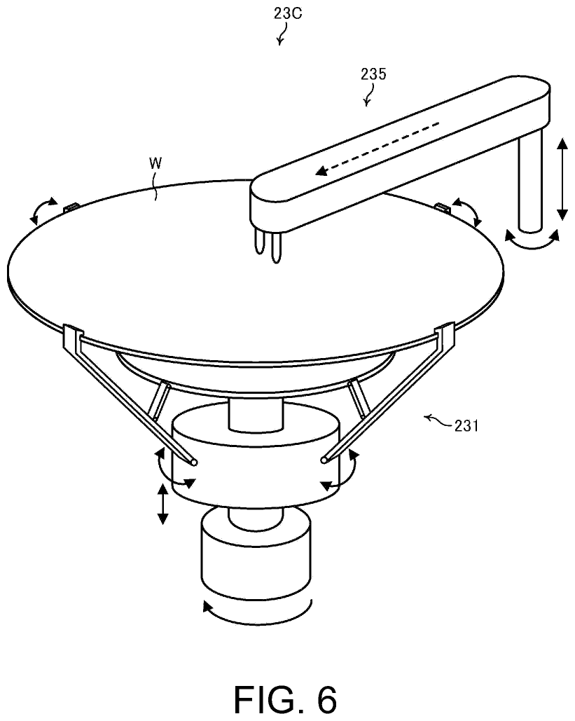

FIG. 6 is a perspective view illustrating an example of the third finishing unit 23C that performs drying processing. The third finishing unit 23C includes: the substrate holder 231, holding the wafer W; and a drying fluid supply 235, supplying a substrate drying fluid to the wafer W. The substrate drying fluid is, for example, isopropyl alcohol (IPA) vapor and pure water (rinsing liquid), or may be a liquid, or may be a two-fluid mixture of a liquid and a gas, or may contain a solid such as dry ice.

In the drying processing performed by the third finishing unit 23C, the wafer W is rotated while being held in a third finishing position PC3 by the substrate holder 231. Then, with the substrate drying fluid being supplied from the drying fluid supply 235 to the surface to be cleaned of the wafer W, the drying fluid supply 235 is moved to a side edge side (outside in a radial direction) of the wafer W. After that, the wafer W is dried by being rotated at high speed.

(Substrate Transfer Part)

As illustrated in FIG. 2, the substrate transfer part 24 includes: the polishing processing transporter 240, as a transfer unit that is movable along a direction (longitudinal direction of the housing 20) in which the first polishing unit 22A and the second polishing unit 22B are arranged side by side and is able to move to the wafer station 23D as a second substrate delivery position PD2; and the finishing processing transporter 241, as a transfer part that is movable along the direction (longitudinal direction of the housing 20) in which the wafer station 23D and the first to third finishing units 23A to 23C are arranged side by side.

The polishing processing transporter 240 is configured to be accessible to the first substrate delivery position PD1, a first transfer position PT1, a second transfer position PT2, and the second substrate delivery position PD2. Accordingly, the polishing processing transporter 240 performs, as the transfer processing for the wafer W, pre-polishing transfer processing for transferring the wafer W from the first substrate delivery position PD1 to the first polishing unit 22A and the second polishing unit 22B (first transfer position PT1 and second transfer position PT2 in the present embodiment), and post-polishing transfer processing for transferring the wafer W after polishing processing from the first polishing unit 22A and the second polishing unit 22B (first transfer position PT1 and second transfer position PT2 in the present embodiment) to the second substrate delivery position PD2.

The first substrate delivery position PD1 is a position where the wafer W is delivered between the carry-in/carry-out robot 211 and the polishing processing transporter 240. The first substrate delivery position PD1 is a position set on the carry-in/carry-out robot 211 side in a movement range of the polishing processing transporter 240, and is accessed by movement of the carry-in/carry-out robot 211.

The first transfer position PT1 and the second transfer position PT2 are respectively positions where the wafer W is delivered between the first polishing unit 22A and the polishing processing transporter 240 and between the second polishing unit 22B and the polishing processing transporter 240. The first transfer position PT1 and the second transfer position PT2 are provided apart by a predetermined distance in the movement range of the polishing processing transporter 240, and are accessed by swing movement of the top ring 221 of each of the first polishing unit 22A and the second polishing unit 22B.

The finishing processing transporter 241 is configured to be accessible to the second substrate delivery position PD2 and the first to third finishing units 23A to 23C. Accordingly, the finishing processing transporter 241 performs, as the transfer processing for the wafer W, pre-finishing transfer processing for transferring the wafer W after polishing processing from the second substrate delivery position PD2 to the first finishing unit 23A in the most upstream process, and in-finishing transfer processing for transferring the wafer W in the middle of finishing processing in the order of finishing processes between the first to third finishing units 23A to 23C. In the present embodiment, the finishing processing transporter 241 performs, as the in-finishing transfer processing, first in-finishing transfer processing for transferring the wafer Win the middle of finishing processing from the first finishing unit 23A to the second finishing unit 23B, and second in-finishing transfer processing for transferring the wafer W in the middle of finishing processing from the second finishing unit 23B to the third finishing unit 23C.

The second substrate delivery position PD2 is a position where the wafer W is delivered between the polishing processing transporter 240 and the finishing processing transporter 241. The second substrate delivery position PD2 is a position set inside the wafer station 23D, and is accessed by movement of each of the polishing processing transporter 240 and the finishing processing transporter 241.

(Control Unit)

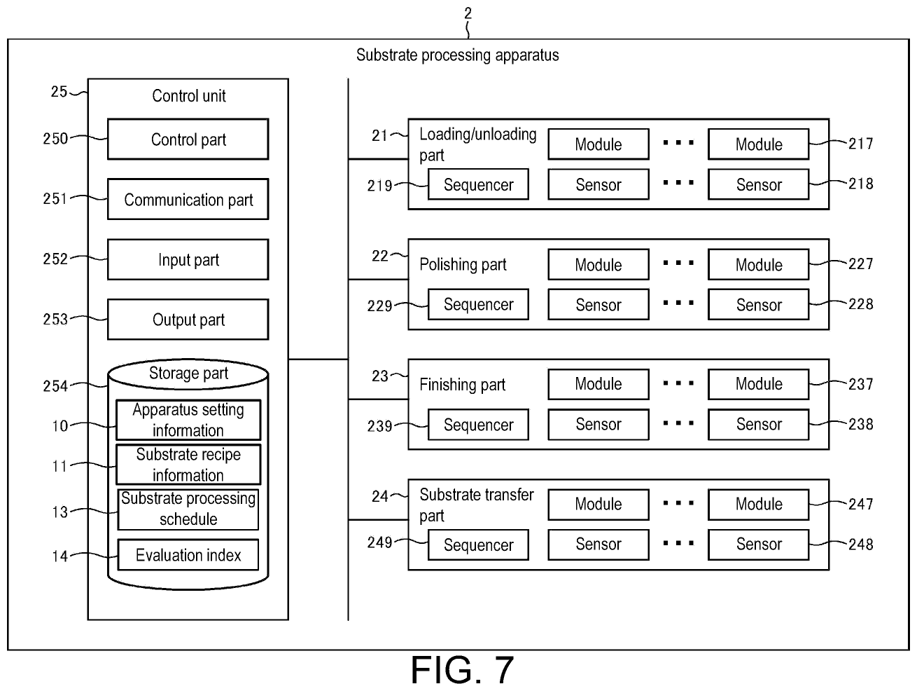

FIG. 7 is a block diagram illustrating an example of the substrate processing apparatus 2. The control unit 25 is electrically connected to the parts 21 to 24 and functions as a control part that controls the parts 21 to 24 in an integrated manner. In the following, a control system (module, sensor, sequencer) of the substrate transfer part 24 is described as an example. Since the basic configurations or functions are also common to the loading/unloading part 21, the polishing part 22 and the finishing part 23, description thereof is omitted.

The substrate transfer part 24 includes: a plurality of modules 247 to be controlled, respectively arranged in each transfer unit (for example, polishing processing transporter 240 or finishing processing transporter 241) provided in the substrate transfer part 24; a plurality of sensors 248, respectively arranged in the plurality of modules 247 and detecting data (detected values) necessary for controlling each module 247; and a sequencer 249, controlling an operation of each module 247 based on the detected value from each sensor 248. The module 247 of the substrate transfer part 24 includes a rotary motor, a linear motor, an air actuator, a hydraulic actuator and the like provided in each transfer unit. The sensor 248 of the substrate transfer part 24 includes, for example, an encoder sensor, a linear sensor, a limit sensor, a non-contact sensor detecting the presence or absence of the wafer W, and the like.

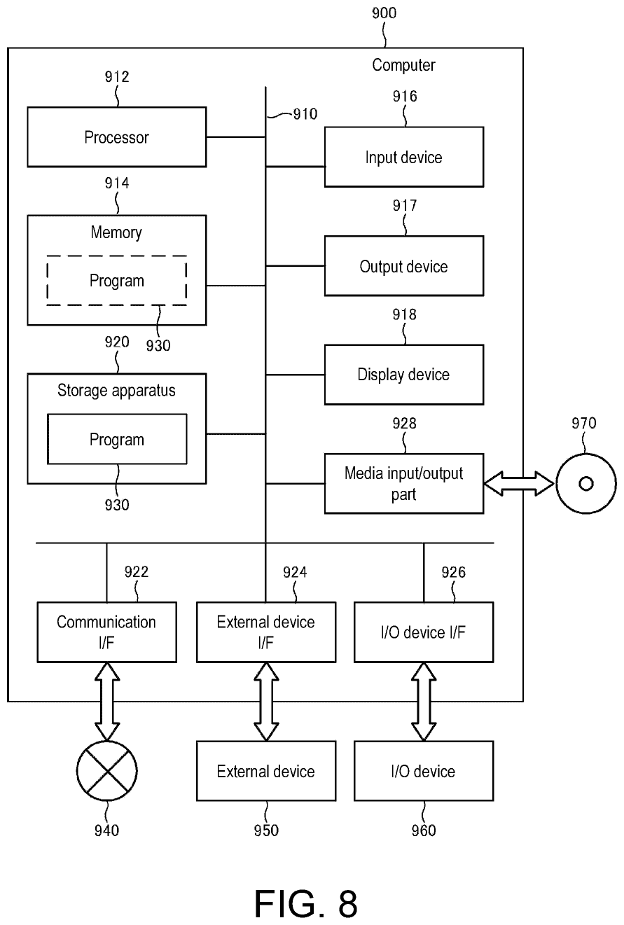

The control unit 25 includes a control part 250, a communication part 251, an input part 252, an output part 253, and a storage part 254. The control unit 25 is composed of, for example, a general-purpose or dedicated computer (see FIG. 8 described later).

The communication part 251 is connected to the network 4, and functions as a communication interface that transmits and receives various data. The input part 252 receives various input operations, and the output part 253 outputs various information via a display screen, a signal tower light, or a buzzer sound, thereby functioning as a user interface.

The storage part 254 stores various programs (such as an operating system (OS), an application program, and a web browser) or data (such as apparatus setting information 10 and substrate recipe information 11) used in an operation of the substrate processing apparatus 2. The apparatus setting information 10 and the substrate recipe information 11 are data editable by the user via the display screen.

The control part 250 acquires a detected value from a plurality of sensors 218, 228, 238, and 248 (hereinafter referred to as “sensor group”) via a plurality of sequencers 219, 229, 239, and 249 (hereinafter referred to as “sequencer group”), and causes a plurality of modules 217, 227, 237, and 247 (hereinafter referred to as “module group”) to operate in cooperation. The substrate processing apparatus 2 controls the parts 21 to 24 by the control part 250 and sequentially performs the polishing processing, the finishing processing, the transfer processing and the like on a plurality of wafers W in the wafer cassette, thereby executing automatic operation.

(Hardware Configuration of Apparatuses)

FIG. 8 is a hardware configuration diagram illustrating an example of a computer 900. The control unit 25 of the substrate processing apparatus 2 and the information processing apparatus 3A each are composed of a general-purpose or dedicated computer 900.

As illustrated in FIG. 8, the computer 900 includes, as its main components, a bus 910, a processor 912, a memory 914, an input device 916, an output device 917, a display device 918, a storage apparatus 920, a communication interface (I/F) 922, an external device I/F 924, an input/output (I/O) device I/F 926, and a media input/output part 928. The above components may be omitted as appropriate depending on the application in which the computer 900 is used.

The processor 912 includes one or more arithmetic processing units (such as a central processing unit (CPU), a microprocessing unit (MPU), a digital signal processor (DSP), and a graphics processing unit (GPU)), and operates as a control part that integrates the entire computer 900. The memory 914 stores various data and a program 930. The memory 914 includes, for example, a volatile memory (such as a DRAM or an SRAM) that functions as a main memory, a non-volatile memory (such as a ROM), and a flash memory.

The input device 916 is composed of, for example, a keyboard, a mouse, a numeric keypad, or an electronic pen, and functions as an input part. The output device 917 is composed of, for example, a sound (voice) output device or a vibration device, and functions as an output part. The display device 918 is composed of, for example, a liquid crystal display, an organic electroluminescence (EL) display, electronic paper, or a projector, and functions as an output part. The input device 916 and the display device 918 may be integrally configured like a touch panel display. The storage apparatus 920 is composed of, for example, a hard disk drive (HDD) or a solid state drive (SSD), and functions as a storage part. The storage apparatus 920 stores various data necessary for executing an operating system or the program 930.

The communication I/F 922 is connected in a wired or wireless manner to a network 940 (which may be the same as the network 4 of FIG. 1) such as the Internet or an intranet, and functions as a communication part that transmits and receives data to and from other computers in accordance with a predetermined communication standard. The external device I/F 924 is connected in a wired or wireless manner to an external device 950 such as a camera, a printer, a scanner, or a reader/writer, and functions as a communication part that transmits and receives data to and from the external device 950 in accordance with a predetermined communication standard. The I/O device I/F 926 is connected to an I/O device 960 such as various sensors and actuators, and functions as a communication part that transmits and receives, to and from the I/O device 960, various signals such as a detection signal from a sensor or a control signal for an actuator, or data. The media input/output part 928 is composed of, for example, a drive device such as a DVD drive or a CD drive, and reads and writes data from and to a medium (non-transitory storage medium) 970 such as a DVD or a CD.

In the computer 900 having the above configuration, the processor 912 calls the program 930 stored in the storage apparatus 920 to the memory 914, executes the program 930, and controls each part of the computer 900 via the bus 910. The program 930 may be stored in the memory 914 instead of the storage apparatus 920. The program 930 may be recorded in an installable file format or an executable file format in the medium 970, and be provided to the computer 900 via the media input/output part 928. The program 930 may be provided to the computer 900 by being downloaded through the network 940 via the communication I/F 922. The computer 900 may realize various functions, which are realized by the processor 912 executing the program 930, by hardware such as a field programmable gate array (FPGA) or an application specific integrated circuit (ASIC).

The computer 900 is composed of, for example, a stationary computer or a portable computer, and is an electronic device of any form. The computer 900 may be a client type computer, or may be a server type computer or a cloud type computer. The computer 900 may also be applied to apparatuses other than the substrate processing apparatus 2 and the information processing apparatus 3A.

(Information Processing Apparatus)

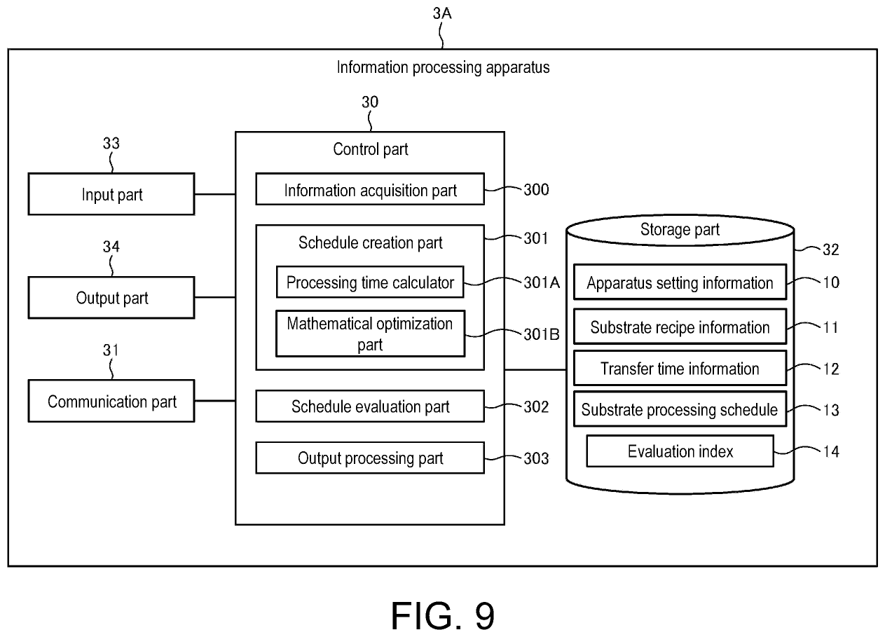

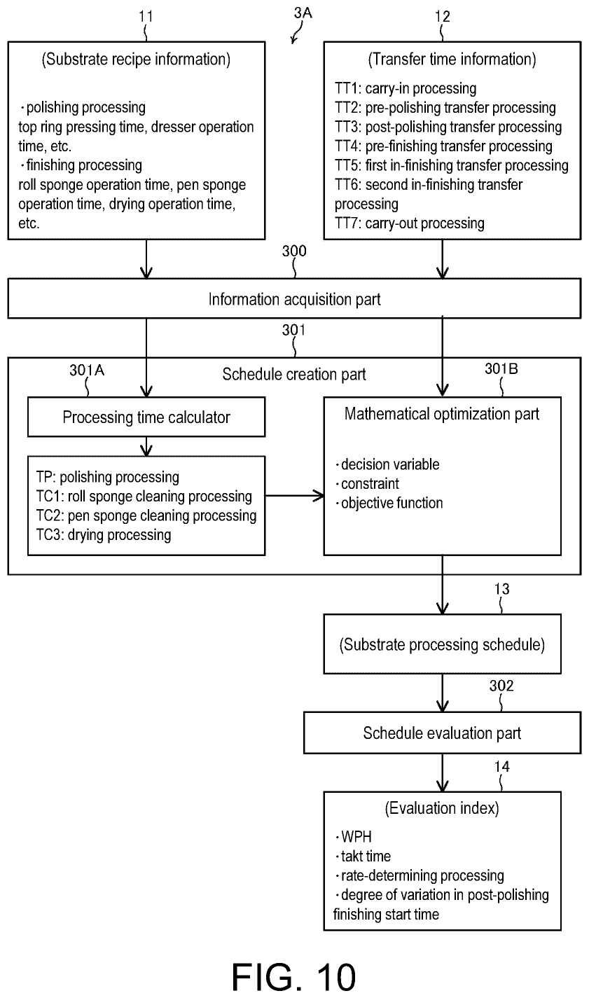

FIG. 9 is a block diagram illustrating an example of the information processing apparatus 3A according to the first embodiment. FIG. 10 is a functional explanatory view illustrating an example of the information processing apparatus 3A according to the first embodiment.

The information processing apparatus 3A includes a control part 30, a communication part 31, a storage part 32, an input part 33, and an output part 34. A specific hardware configuration of the parts 30 to 34 illustrated in FIG. 9 is composed of the general-purpose or dedicated computer 900 illustrated in FIG. 8, and thus, detailed description thereof is omitted.

The control part 30 functions as an information acquisition part 300, a schedule creation part 301, a schedule evaluation part 302, and an output processing part 303. The communication part 31 is connected to an external device (for example, substrate processing apparatus 2) via the network 4, and functions as a communication interface that transmits and receives various data. The storage part 32 stores various programs (such as an operating system or an information processing program) or data (apparatus setting information 10, substrate recipe information 11, transfer time information 12, substrate processing schedule 13, and evaluation index 14) used in an operation of the information processing apparatus 3A. The input part 33 receives various input operations, and the output part 34 outputs various information via a display screen or a voice, thereby functioning as a user interface.

The information acquisition part 300 acquires the substrate recipe information 11 and the transfer time information 12 by, for example, transmitting and receiving data to and from the substrate processing apparatus 2 via the communication part 31, or referring to the storage part 32. The substrate recipe information 11 and the transfer time information 12 may be based on a user's input operation, or may be acquired from an external production management device (not illustrated).

The substrate recipe information 11 is information indicating processing content of the polishing processing and the finishing processing. The processing content of the polishing processing includes, for example, a table rotation speed of the polishing table 220, a top ring pressing time by the top ring 221, a wafer pressing load, a wafer rotation speed, a supply amount and a supply timing of the polishing fluid supplied from the polishing fluid supply 222, a dresser operation time of the dresser 223, and an atomizer operation time of the atomizer 224. The processing content of the finishing processing includes, for example, a roll sponge operation time, a roll sponge rotation speed, a wafer rotation speed, a supply amount and a supply timing of the substrate cleaning fluid in the roll sponge cleaning processing, a pen sponge operation time, a pen sponge rotation speed, a wafer rotation speed, a supply amount and a supply timing of the substrate cleaning fluid in the pen sponge cleaning processing, and a drying operation time, a wafer rotation speed, and a supply amount and a supply timing of the substrate drying fluid in the drying processing. The substrate recipe information 11 may be set for each wafer W, or may be set for each plurality of wafers constituting a lot.

The transfer time information 12 is information indicating transfer times TT1 to TT7 required for each of the carry-in processing, the pre-polishing transfer processing, the post-polishing transfer processing, the pre-finishing transfer processing, the in-finishing transfer processing (in the present embodiment, first in-finishing transfer processing and second in-finishing transfer processing), and the carry-out processing, as the transfer processing. The transfer times TT1 to TT7 may be, for example, measured values obtained by measuring a time during which the transfer unit (for example, carry-in/carry-out robot 211, polishing processing transporter 240, or finishing processing transporter 241) actually operates, or may be acquired from the substrate processing apparatus 2 or the external production management device if the measured values of the transfer time are stored in the substrate processing apparatus 2 or the external production management device. The transfer times TT1 to TT7 may be theoretical values calculated from the specifications of the transfer unit. If a moving speed of the transfer unit is contained in the apparatus setting information 10, the apparatus setting information 10 may be acquired from the substrate processing apparatus 2 or the storage part 32, and the transfer times TT1 to TT7 may be calculated based on the apparatus setting information 10. Furthermore, the transfer times TT1 to TT7 may be inferred values considering an error (actual operation error) between the above theoretical values and the measured values obtained when the transfer unit actually operates. For example, the actual operation error may be calculated using an estimation model in machine learning or the like. The transfer time information 12 may be set for each wafer W, or may be set for each plurality of wafers constituting a lot.

The schedule creation part 301 creates the substrate processing schedule 13 for sequentially performing each processing on a predetermined number of wafers W in the substrate processing apparatus 2. Specifically, based on the substrate recipe information 11 and the transfer time information 12 acquired by the information acquisition part 300, the schedule creation part 301 creates the substrate processing schedule 13 by determining a start timing of each processing so that a final processing end time during which the last wafer W after finishing processing is carried out to the substrate carry-out position PE is shortest. The schedule creation part 301 may create the substrate processing schedule 13 by determining the start timing of each processing so that, instead of or in addition to that the final processing end time is shortest, a post-polishing finishing start time from an end timing of the polishing processing to a start timing of the finishing processing in the most upstream process is uniform and minimized.

The schedule creation part 301 according to the present embodiment includes, as its configuration, a processing time calculator 301A and a mathematical optimization part 301B.

Based on the substrate recipe information 11, the processing time calculator 301A calculates a polishing time required for the polishing processing and a finishing time required for the finishing processing. For example, the processing time calculator 301A calculates a polishing time TP required for the polishing processing based on a set value relating to polishing time in the processing content of the polishing processing indicated in the substrate recipe information 11. The processing time calculator 301A calculates the finishing time required for the finishing processing based on a set value relating to finishing time in the processing content of the finishing processing indicated in the substrate recipe information 11. In the present embodiment, as the finishing time, a finishing time TC1 required for the roll sponge cleaning processing, a finishing time TC2 required for the pen sponge cleaning processing, and a finishing time TC3 required for the drying processing are calculated. The polishing time TP or the finishing times TC1 to TC3 may be obtained considering, for example, measured values obtained by measuring a time during which the polishing units 22A and 22B or the finishing units 23A to 23C actually operate. At that time, for example, if the measured values are stored in the substrate processing apparatus 2 or the external production management device, the processing time calculator 301A may acquire the measured values as the polishing time TP or the finishing times TC1 to TC3 from the substrate processing apparatus 2 or the external production management device, or may, based on the measured values, correct the polishing time TP or the finishing times TC1 to TC3 calculated from the substrate recipe information 11.

The mathematical optimization part 301B formulates the substrate processing schedule 13 into an optimization problem by mathematical optimization, and searches for an optimal solution, thereby creating the substrate processing schedule 13. As a mathematical optimization method, for example, mixed-integer linear programming (MILP) may be used, or other methods may be used. As a method for searching for the optimal solution, any search algorithm such as an exact algorithm, an approximation algorithm, or a heuristic algorithm may be used.

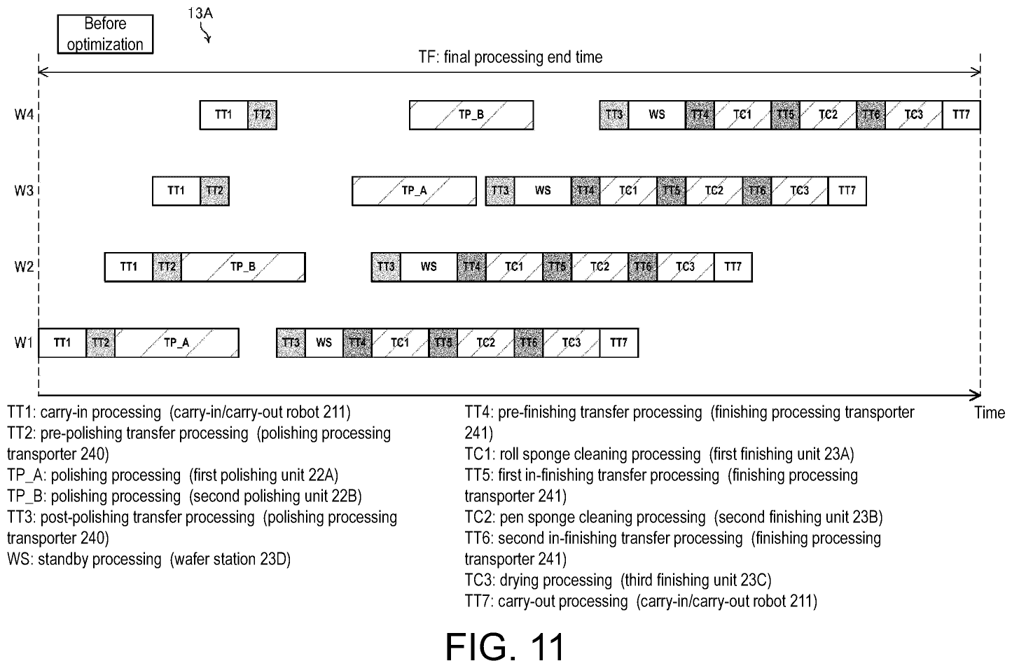

FIG. 11 illustrates an example of a substrate processing schedule 13A before mathematical optimization. The substrate processing schedule 13A illustrated in FIG. 11 is created as, for example, a default before (or during) optimization by the mathematical optimization part 301B. In FIG. 11, for simplification, the substrate processing schedule 13A for four wafers W is illustrated. However, the number of wafers W in the substrate processing schedule 13A may be changed as appropriate. The substrate processing schedule 13A may be actual values obtained by chronologically recording each processing when automatic operation is executed by the substrate processing apparatus 2 before optimization by the mathematical optimization part 301B.

In automatic operation of the substrate processing apparatus 2, each processing is performed in such a manner that, while the order of performing each processing is followed, those among the processings that are able to be simultaneously performed are performed in parallel, and those among the processings that are unable to be simultaneously performed are performed in series. Therefore, by performing mathematical optimization in which the start timing of each processing is determined as a decision variable for mathematical optimization with a processing order condition that defines the order of performing each processing and a simultaneous processing condition that defines which of the processings are able or unable to be simultaneously performed as constraints for mathematical optimization, and with minimizing a final processing end time TF as an objective function for mathematical optimization that includes the polishing time TP and the finishing times TC1 to TC3 calculated by the processing time calculator 301A and the transfer times TT1 to TT7 indicated in the transfer time information 12 as variables, the mathematical optimization part 301B creates the substrate processing schedule 13.

In the substrate processing apparatus 2 according to the present embodiment, as processing order condition, the following order is determined: carry-in processing (TT1), pre-polishing transfer processing (TT2), polishing processing (TP), post-polishing transfer processing (TT3), standby processing (WS), pre-finishing transfer processing (TT4), roll sponge cleaning processing (TC1), first in-finishing transfer processing (TT5), pen sponge cleaning processing (TC2), second in-finishing transfer processing (TT6), drying processing (TC3), and carry-out processing (TT7). As the simultaneous processing condition, polishing processing (TP_A) by the first polishing unit 22A and polishing processing (TP_B) by the second polishing unit 22B are determined as processings that are able to be simultaneously performed, and the pre-finishing transfer processing (TT4), the first in-finishing transfer processing (TT5) and the second in-finishing transfer processing (TT6) are determined as processings that are unable to be simultaneously performed.

At that time, the mathematical optimization part 301B may perform mathematical optimization by considering a post-polishing finishing start time TW from an end timing of the polishing processing (TP_A, TP_B) to a start timing of the finishing processing (TC1) in the most upstream process.

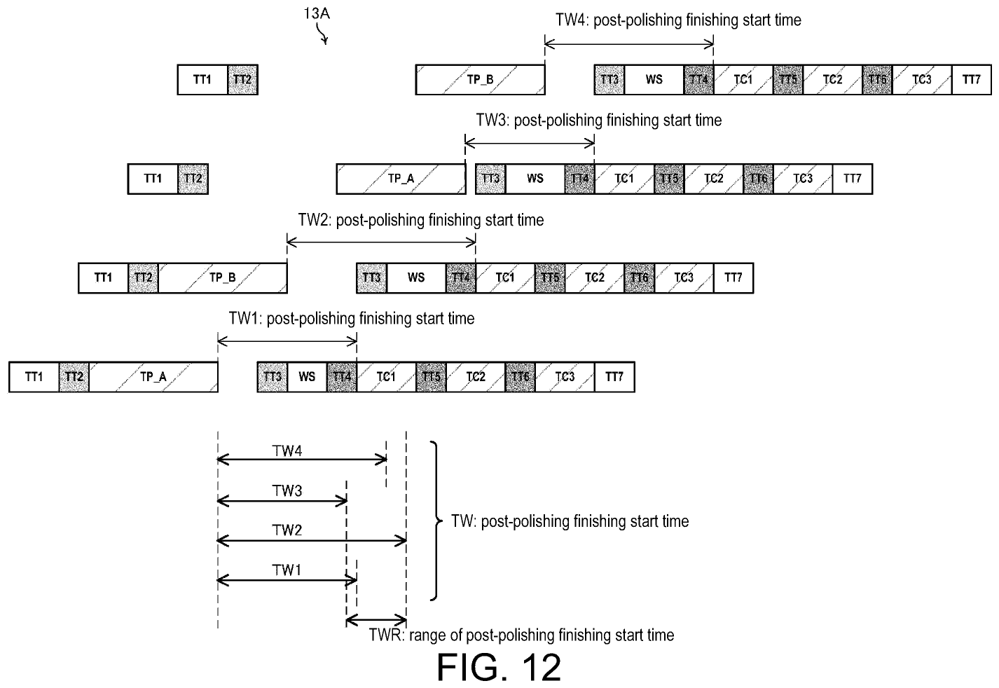

FIG. 12 illustrates an example of the post-polishing finishing start time TW and a range TWR thereof. As illustrated in FIG. 12, in the substrate processing schedule 13A, post-polishing finishing start times TW1 to TW4 for the four wafers W are respectively defined. The range TWR of the post-polishing finishing start times TW1 to TW4 is defined as a differential value between the minimum value TW3 and the maximum value TW2 of the post-polishing finishing start times TW1 to TW4.

For example, the mathematical optimization part 301B may perform mathematical optimization further with a post-polishing finishing start range condition that defines the range TWR of the post-polishing finishing start time TW as a constraint. The substrate processing schedule 13 is created so that, if the range TWR of the post-polishing finishing start time TW is defined to be, for example, within 1 second, a difference between the minimum value and the maximum value is within 1 second. Accordingly, when automatic operation is performed for a plurality of wafers W, variation in the post-polishing finishing start time TW among the plurality of wafers W can be reduced, and the post-polishing finishing start time TW can be made uniform.

The mathematical optimization part 301B may perform mathematical optimization further with minimizing a total value, an average value or a maximum value of the post-polishing finishing start time TW as an objective function. In that case, for example, the objective function may be defined by combining minimization of the final processing end time TF with minimization of the post-polishing finishing start time TW using a weighting factor or the like. Accordingly, when automatic operation is performed for a plurality of wafers W, a waiting time from when the polishing processing (TP_A, TP_B) is performed until when the finishing processing (TC1) is performed can be reduced. Furthermore, the mathematical optimization part 301B may perform mathematical optimization further with minimizing a degree of variation (for example, standard deviation, variance, or differential value between maximum value and minimum value) in the post-polishing finishing start time TW as an objective function.

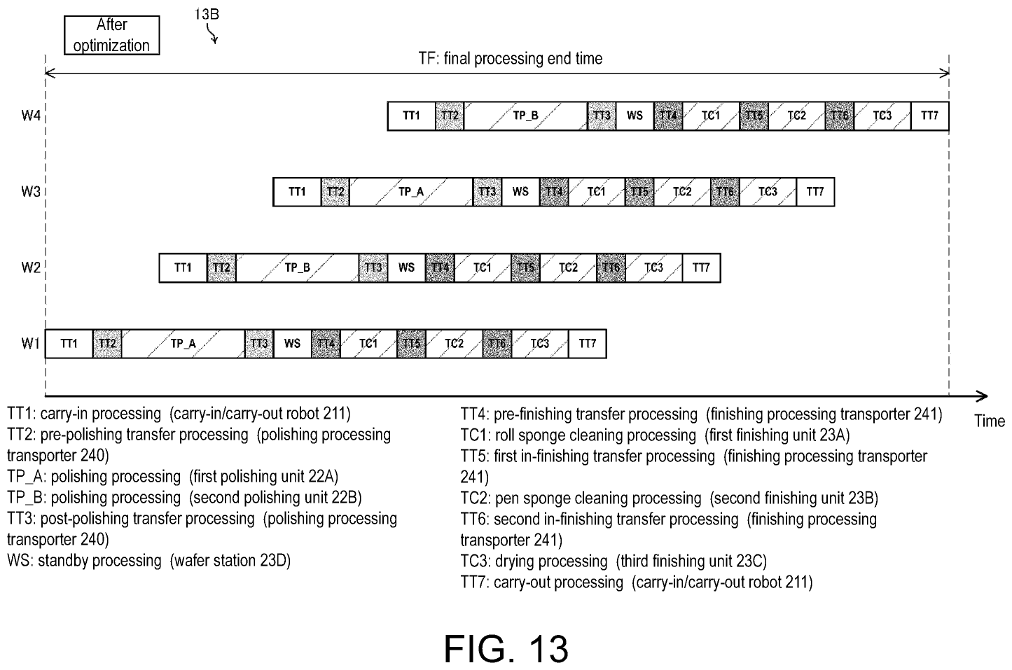

FIG. 13 illustrates an example of a substrate processing schedule 13B after mathematical optimization, which is created by the schedule creation part 301. The substrate processing schedule 13B illustrated in FIG. 13 is created by mathematical optimization by the schedule creation part 301. Compared with the substrate processing schedule 13A before mathematical optimization as illustrated in FIG. 11, in the substrate processing schedule 13B after mathematical optimization, the order of starting and the start timing of each processing are changed.

The schedule evaluation part 302 evaluates the substrate processing schedule 13 created by the schedule creation part 301, and calculates the evaluation index 14 of the substrate processing schedule 13 as an evaluation result. The evaluation index 14 of the substrate processing schedule 13 includes at least one of the number of wafers W processed per unit time (wafer per hour, WPH), takt time of each processing, rate-determining processing among the processings that requires the longest processing time, and degree of variation in the post-polishing finishing start time TW.

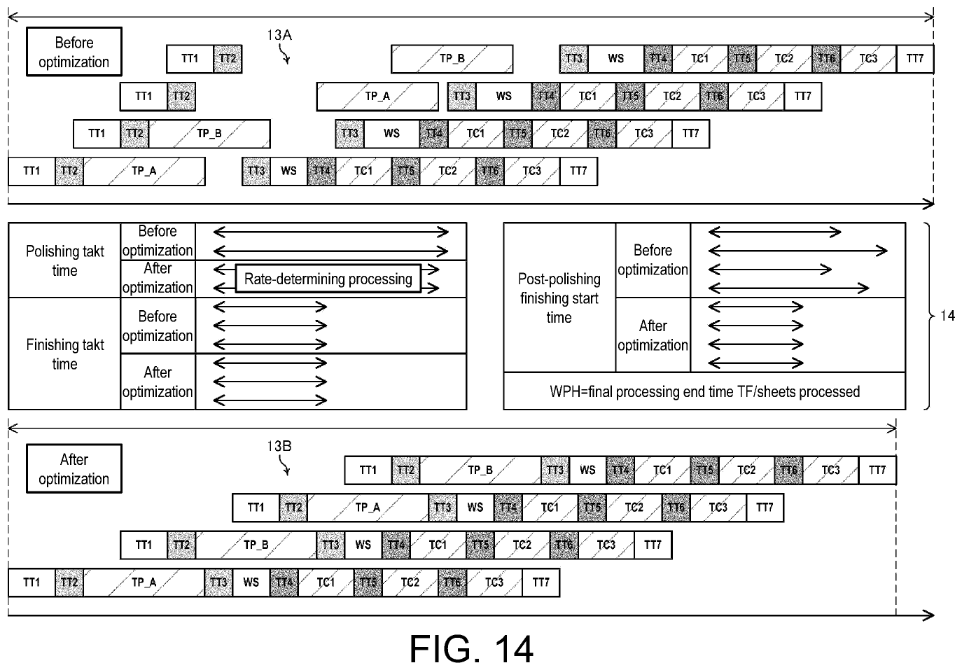

FIG. 14 illustrates an example of the evaluation index 14 with respect to the substrate processing schedules 13A and 13B. WPH is calculated by dividing the final processing end time TF by the number of sheets processed. As the takt time of each processing, the takt time of the polishing processing and the finishing processing is calculated. As the degree of variation in the post-polishing finishing start time TW, for example, a standard deviation, a variance, and a differential value between the maximum value and the minimum value are calculated. In the example of FIG. 14, the takt time of the polishing processing (TP_A, TP_B) in the substrate processing schedule 13B after mathematical optimization is shorter than that in the substrate processing schedule 13A before mathematical optimization. The polishing processing (TP_A, TP_B) is specified as rate-determining processing.

The output processing part 303 performs output processing for outputting the substrate processing schedule 13 created by the schedule creation part 301 and the evaluation index 14 calculated by the schedule evaluation part 302. For example, the output processing part 303 may display and output the substrate processing schedule 13 and the evaluation index 14 by the output part 34 or may store the substrate processing schedule 13 and the evaluation index 14 in the storage part 32. The output processing part 303 may transmit the substrate processing schedule 13 to the substrate processing apparatus 2 by the communication part 31, such that the substrate processing apparatus 2 performs automatic operation in accordance with the substrate processing schedule 13.

(Information Processing Method)

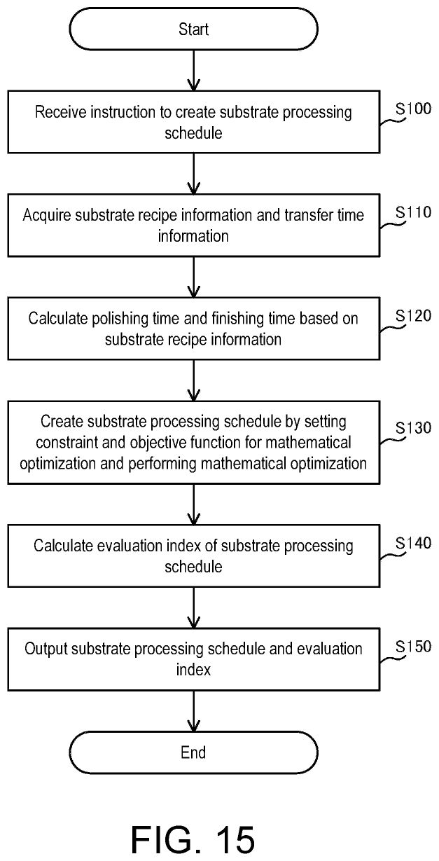

FIG. 15 is a flowchart illustrating an example of an information processing method performed by the information processing apparatus 3A according to the first embodiment.

First, in step S100, the user gives an instruction on a creation condition (for example, a lot number of the wafer W as a target of automatic operation, a model number of the substrate processing apparatus 2 that performs automatic operation, or the number of sheets processed) for the substrate processing schedule 13 and an instruction to start creating the substrate processing schedule 13 on, for example, a substrate processing optimization screen displayed on the information processing device 3A, whereby the information processing apparatus 3A receives an input operation thereof.

Next, in step S110, the information acquisition part 300 acquires the substrate recipe information 11 and the transfer time information 12 based on the input operation received in step S100. For example, if an instruction on a lot number is given, the substrate recipe information 11 associated with the lot number is acquired; if an instruction on a model number of the substrate processing apparatus 2 is given, the transfer time information 12 associated with the model number is acquired.

Next, in step S120, based on the substrate recipe information 11 acquired in step S110, the processing time calculator 301A calculates a polishing time required for the polishing processing and a finishing time required for the finishing processing.

Next, in step S130, the mathematical optimization part 301B sets the processing order condition, the simultaneous processing condition, and the post-polishing finishing start range condition as constraints for mathematical optimization, sets minimization of the final processing end time TF and minimization of the post-polishing finishing start time TW as objective functions for mathematical optimization that include the polishing time and the finishing time calculated in step S120 as well as the transfer time indicated in the transfer time information 12 acquired in step S110 as variables, and performs mathematical optimization, thereby creating the substrate processing schedule 13.

Next, in step S140, based on the substrate processing schedule 13 created in step S130, the schedule evaluation part 302 calculates the evaluation index 14 of the substrate processing schedule 13.

Then, in step S150, the output processing part 303 performs output processing for outputting the substrate processing schedule 13 created in step S130 and the evaluation index 14 calculated in step S140, and the series of steps of the information processing method illustrated in FIG. 15 are ended. In the above information processing method, step S110 corresponds to an information acquisition process, steps S120 and S130 correspond to a schedule creation process, step S140 corresponds to a schedule evaluation process, and step S150 corresponds to an output processing process.

As described above, according to the information processing apparatus 3A and the information processing method according to the present embodiment, based on the substrate recipe information 11 and the transfer time information 12, the schedule creation part 301 creates the substrate processing schedule 13 by determining the start timing of each processing so that the final processing end time TF is shortest. Accordingly, since the substrate processing schedule 13 reflects the processing content of each processing or the time required for each processing, the substrate processing schedule 13 can be appropriately created.

### Second Embodiment

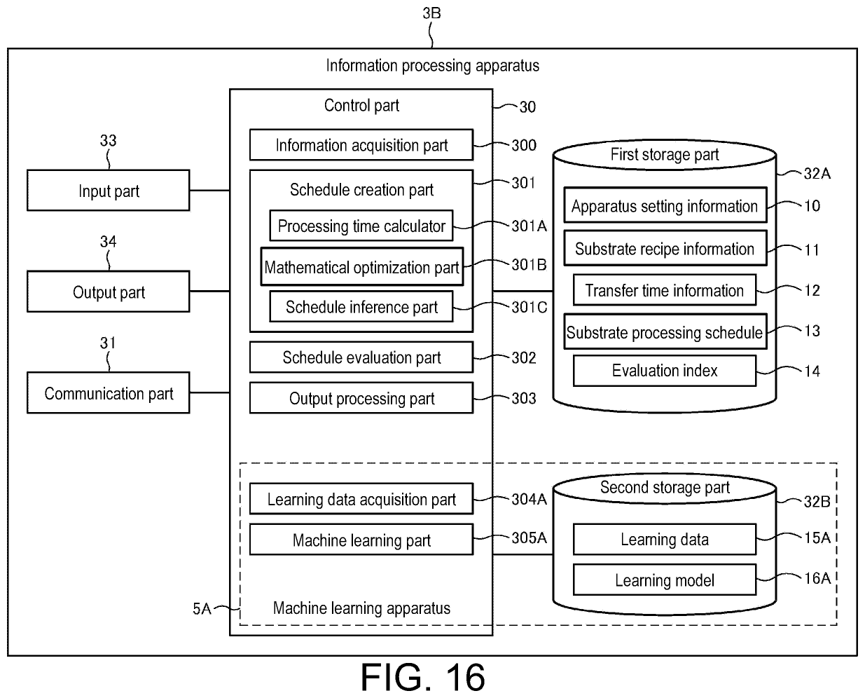

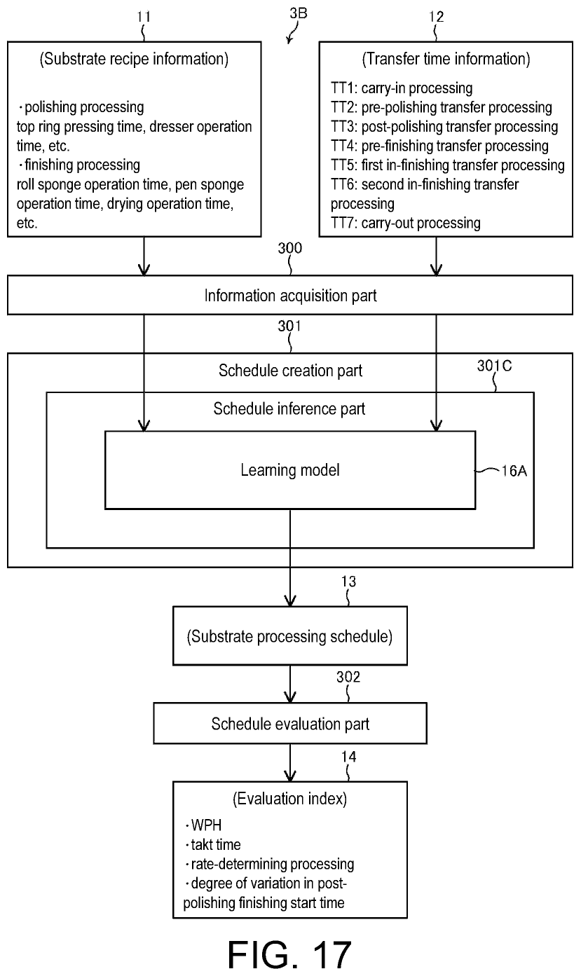

FIG. 16 is a block diagram illustrating an example of an information processing apparatus 3B according to a second embodiment. FIG. 17 is a functional explanatory view illustrating an example of the information processing apparatus 3B according to the second embodiment.

The information processing apparatus 3B according to the second embodiment differs from the information processing apparatus 3A according to the first embodiment in the following. That is, the information processing apparatus 3B operates as a machine learning apparatus 5A that generates a learning model 16A by machine learning using learning data 15A, and a schedule inference part 301C of the schedule creation part 301 creates the substrate processing schedule 13 using the learning model 16A generated by the machine learning apparatus 5A. The other configurations and operations of the substrate processing apparatus 2 and the information processing apparatus 3B are the same as those of the first embodiment, and thus, the same reference numerals are assigned and detailed description thereof is omitted.

The control part 30 further functions as a learning data acquisition part 304A and a machine learning part 305A. In the present embodiment, the machine learning apparatus 5A is described as being incorporated in the information processing apparatus 3B. However, the machine learning apparatus 5A and the information processing apparatus 3B may be configured as separate apparatuses. In that case, the learning model 16A that has been learned may be provided to the information processing apparatus 3B via the network 4 or any storage medium or the like.

Like the storage part 32 of the first embodiment, a first storage part 32A stores various programs or data. A second storage part 32B stores the learning data 15A and the learning model 16A. The second storage part 32B functions as a learning data storage part that stores the learning data 15A and a learned model storage part that stores a learned learning model. The first storage part 32A and the second storage part 32B may each be composed of a single storage part, or may each be an external storage device.

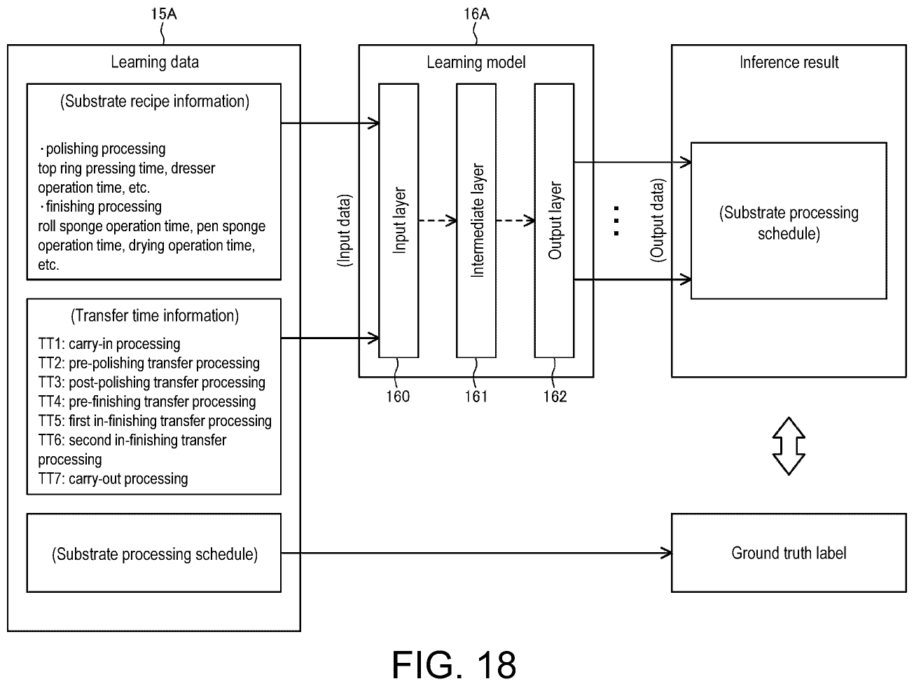

FIG. 18 illustrates an example of the learning data 15A and the learning model 16A according to the second embodiment. The learning data 15A used in machine learning of the learning model 16A is configured in which the substrate recipe information 11 and the transfer time information 12 are input data, and the substrate processing schedule 13 is output data. The transfer time information 12 may be any of a measured value, a theoretical value, and an inferred value.

The learning data acquisition part 304A, for example, performs mathematical optimization on each combination of a plurality of substrate recipe information 11 with different processing contents and a plurality of transfer time information 12 with different transfer times in cooperation with the mathematical optimization part 301B, thereby creating the substrate processing schedule 13 separately. Then, the learning data acquisition part 304A acquires a plurality of sets of learning data 15A by associating the substrate recipe information 11 and the transfer time information 12 with the substrate processing schedule 13 created from the substrate recipe information 11 and the transfer time information 12 regarding each combination, and stores the plurality of sets of learning data 15A in the second storage part 32B.

The learning model 16A employs, for example, a neural network structure, and includes an input layer 160, an intermediate layer 161, and an output layer 162. A synapse (not illustrated) connecting each neuron is provided between each layer, and a weight is associated with each synapse. A weight parameter group including the weights of each synapse is adjusted by machine learning. The input layer 160 includes a number of neurons corresponding to the substrate recipe information 11 and the transfer time information 12 as the input data, and each value of the substrate recipe information 11 and the transfer time information 12 is input to each neuron. The output layer 162 includes a number of neurons corresponding to the substrate processing schedule 13 as the output data, and a prediction result (inference result) of the substrate processing schedule 13 with respect to the substrate recipe information 11 and the transfer time information 12 is output as the output data.

The machine learning part 305A implements machine learning using the plurality of sets of learning data 15A stored in the second storage part 32B. That is, the machine learning part 305A inputs a plurality of sets of learning data 15A to the learning model 16A, and causes the learning model 16A to learn a correlation between the input data and the output data contained in the learning data 15A, thereby generating the learning model 16A that has been learned. The learning model 16A (specifically, adjusted weight parameter group) is stored in the second storage part 32B.

The schedule inference part 301C inputs the substrate recipe information 11 and the transfer time information 12 acquired by the information acquisition part 300 to the learning model 16A, thereby creating the substrate processing schedule 13 with respect to the substrate recipe information 11 and the transfer time information 12.

(Machine Learning Method)

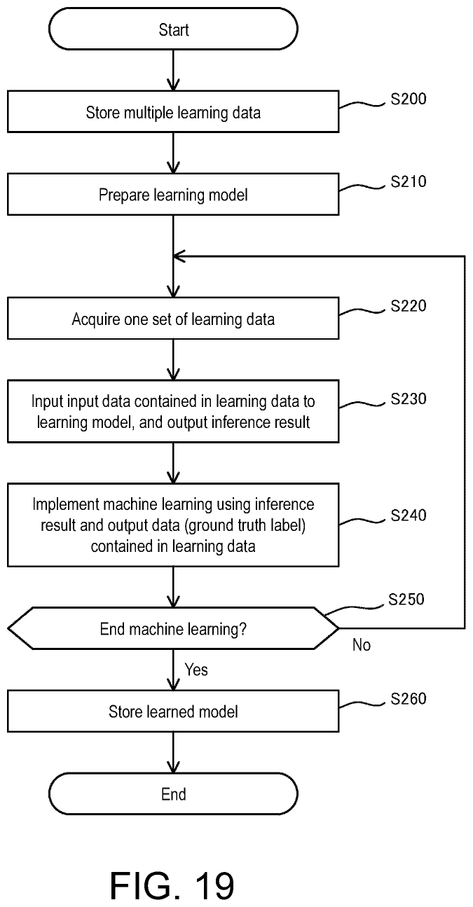

FIG. 19 is a flowchart illustrating an example of a machine learning method performed by the machine learning apparatus 5A.

First, in step S200, as a preparation for starting machine learning, the learning data acquisition part 304A acquires a desired number of learning data 15A in cooperation with the mathematical optimization part 301B, and stores the acquired learning data 15A in the second storage part 32B.

Next, in step S210, in order to start machine learning, the machine learning part 305A prepares the learning model 16A before learning in which the weight of each synapse is set to an initial value.

Next, in step S220, the machine learning part 305A acquires, for example, one set of learning data 15A, randomly from the plurality of sets of learning data 15A stored in the second storage part 32B.

Next, in step S230, the machine learning part 305A inputs fluid supply information (input data) contained in the one set of learning data 15A to the input layer 160 of the prepared learning model 16A before (or during) learning. As a result, output data as an inference result is output from the output layer 162 of the learning model 16A, and the output data is generated by the learning model 16A before (or during) learning. Hence, in a state before (or during) learning, the output data output as the inference result indicates information different from the output data (ground truth label) contained in the learning data 15A.

Next, in step S240, the machine learning part 305A compares the output data (ground truth label) contained in the one set of learning data 15A acquired in step S220 with the output data (inference result) output as the inference result from the output layer 162 in step S230, and implements processing (backpropagation) for adjusting the weight of each synapse, thereby implementing machine learning.

Next, in step S250, the machine learning part 305A determines whether a predetermined learning end condition is satisfied based on, for example, an evaluation value of an error function based on the output data (ground truth label) contained in the learning data 15A and the output data as the inference result, or a remaining number of unlearned learning data 15A stored in the second storage part 32B.

In step S250, if the machine learning part 305A determines that the learning end condition is not satisfied and machine learning is to be continued (No in step S250), the process returns to step S220, and the processes of steps S220 to S240 are implemented a plurality of times on the learning model 16A during learning using the unlearned learning data 15A. On the other hand, in step S250, if the machine learning part 305A determines that the learning end condition is satisfied and machine learning is to be ended (Yes in step S250), the process proceeds to step S260.

Then, in step S260, the machine learning part 305A stores in the second storage part 32B the learning model 16A that has been learned (adjusted weight parameter group) generated by adjusting the weight associated with each synapse, and the series of steps of the machine learning method illustrated in FIG. 19 are ended. In the above machine learning method, step S200 corresponds to a learning data storage process, steps S210 to S250 correspond to a machine learning process, and step S260 corresponds to a learned model storage process.

(Information Processing Method)

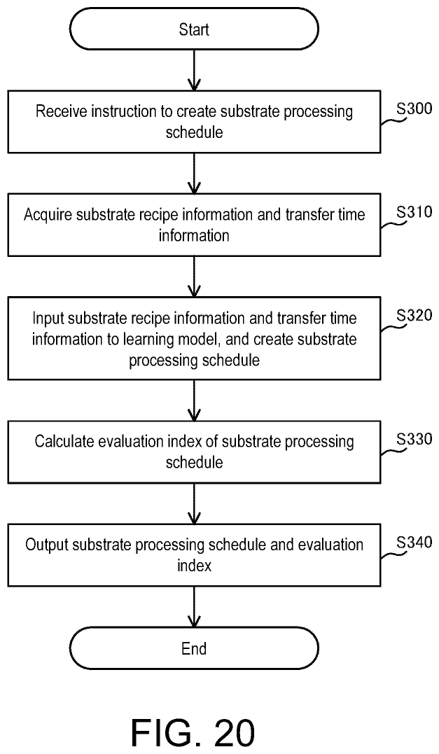

FIG. 20 is a flowchart illustrating an example of an information processing method performed by the information processing apparatus 3B according to the second embodiment.

First, in step S300, like the first embodiment, the user gives an instruction on the creation condition for the substrate processing schedule 13 and an instruction to start creating the substrate processing schedule 13. Thereupon, in step S310, the information acquisition part 300 acquires the substrate recipe information 11 and the transfer time information 12.

Next, in step S320, based on the output data output from the learning model 16A by input of the substrate recipe information 11 and the transfer time information 12 acquired in step S310 to the learning model 16A as input data, the schedule inference part 301C creates the substrate processing schedule 13 with respect to the substrate recipe information 11 and the transfer time information 12.

Next, in step S330, based on the substrate processing schedule 13 created in step S320, the schedule evaluation part 302 calculates the evaluation index 14 of the substrate processing schedule 13. Then, in step S340, the output processing part 303 performs output processing for outputting the substrate processing schedule 13 created in step S320 and the evaluation index 14 calculated in step S330, and the series of steps of the information processing method illustrated in FIG. 20 are ended. In the above information processing method, step S310 corresponds to the information acquisition process, step S320 corresponds to the schedule creation process, step S330 corresponds to the schedule evaluation process, and step S340 corresponds to the output processing process.

As described above, according to the information processing apparatus 3B and the information processing method according to the present embodiment, the schedule inference part 301C is able to create the substrate processing schedule 13 by inputting the substrate recipe information 11 and the transfer time information 12 to the learning model 16A.

### Third Embodiment

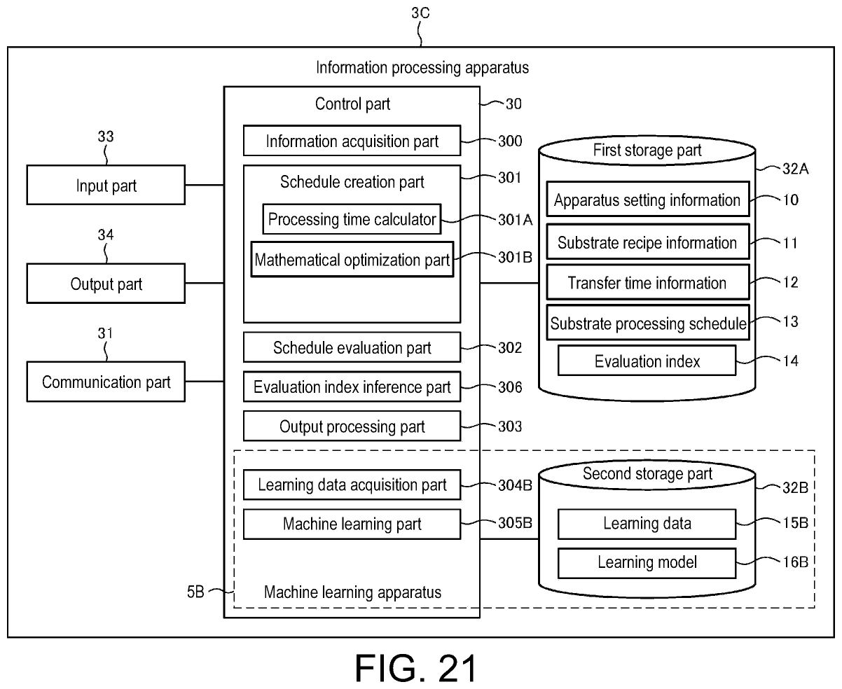

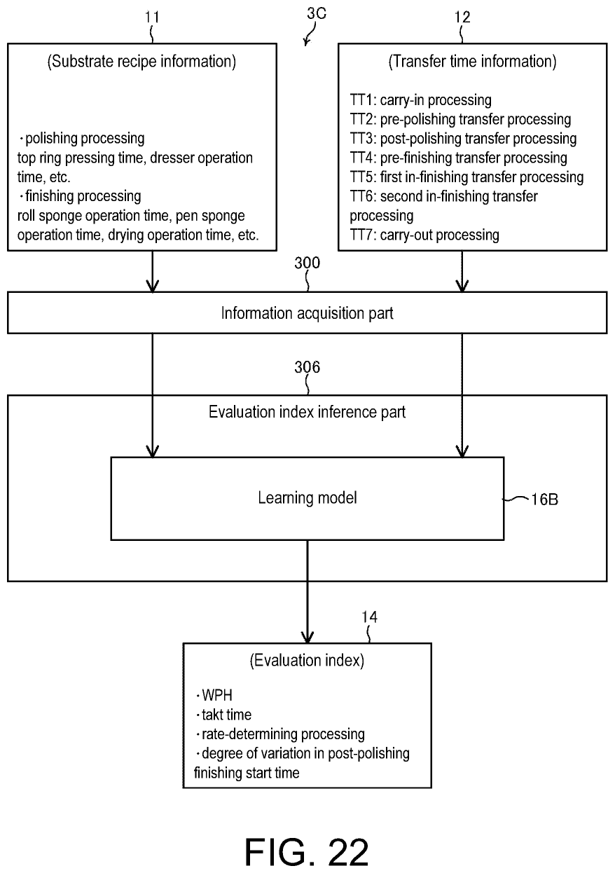

FIG. 21 is a block diagram illustrating an example of an information processing apparatus 3C according to a third embodiment. FIG. 22 is a functional explanatory view illustrating an example of the information processing apparatus 3C according to the third embodiment.

The information processing apparatus 3C according to the third embodiment differs from the information processing apparatus 3A according to the first embodiment in the following. That is, the information processing apparatus 3C operates as a machine learning apparatus 5B that generates a learning model 16B by machine learning using learning data 15B, and an evaluation index inference part 306 infers the evaluation index 14 of the substrate processing schedule 13 using the learning model 16B generated by the machine learning apparatus 5B. The other configurations and operations of the substrate processing apparatus 2 and the information processing apparatus 3C are the same as those of the first embodiment, and thus, the same reference numerals are assigned and detailed description thereof is omitted.

The control part 30 further functions as a learning data acquisition part 304B, a machine learning part 305B, and the evaluation index inference part 306. In the present embodiment, like the second embodiment, the machine learning apparatus 5B is described as being incorporated into the information processing apparatus 3C. However, the machine learning apparatus 5B and the information processing apparatus 3C may be configured as separate apparatuses. In that case, the learning model 16B that has been learned may be provided to the information processing apparatus 3C via the network 4 or any storage medium or the like.

Like the storage part 32 of the first embodiment, the first storage part 32A stores various programs or data. The second storage part 32B stores the learning data 15B and the learning model 16B. The second storage part 32B functions as a learning data storage part that stores the learning data 15B and a learned model storage part that stores a learned learning model.

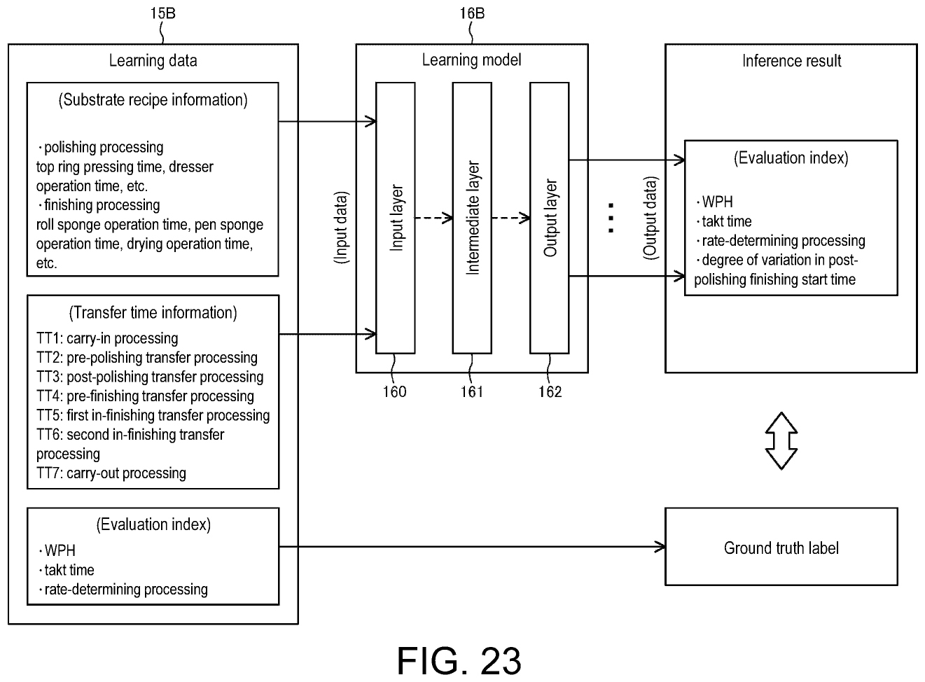

FIG. 23 illustrates an example of the learning data 15B and the learning model 16B according to the third embodiment. The learning data 15B used in machine learning of the learning model 16B is configured in which the substrate recipe information 11 and the transfer time information 12 are input data, and the evaluation index 14 of the substrate processing schedule 13 is output data.

The learning data acquisition part 304B, for example, calculates the evaluation index 14 of the substrate processing schedule 13 for each combination of a plurality of substrate recipe information 11 with different processing contents and a plurality of transfer time information 12 with different transfer times in cooperation with the mathematical optimization part 301B and the schedule evaluation part 302. Then, the learning data acquisition part 304B acquires a plurality of sets of learning data 15B by associating the substrate recipe information 11 and the transfer time information 12 with the evaluation index 14 of the substrate processing schedule 13 calculated from the substrate recipe information 11 and the transfer time information 12 regarding each combination, and stores the plurality of sets of learning data 15B in the second storage part 32B.

Like the second embodiment, the learning model 16B employs, for example, a neural network structure, and includes the input layer 160, the intermediate layer 161, and the output layer 162. The input layer 160 includes a number of neurons corresponding to the substrate recipe information 11 and the transfer time information 12 as the input data, and each value of the substrate recipe information 11 and the transfer time information 12 is input to each neuron. The output layer 162 includes a number of neurons corresponding to the evaluation index 14 of the substrate processing schedule 13 as the output data, and a prediction result (inference result) of the evaluation index 14 of the substrate processing schedule 13 with respect to the substrate recipe information 11 and the transfer time information 12 is output as the output data.

The machine learning part 305B implements machine learning using the plurality of sets of learning data 15B stored in the second storage part 32B. That is, the machine learning part 305B inputs a plurality of sets of learning data 15B to the learning model 16B, and causes the learning model 16B to learn a correlation between the input data and the output data contained in the learning data 15B, thereby generating the learning model 16B that has been learned. The learning model 16B (specifically, adjusted weight parameter group) is stored in the second storage part 32B. Since the machine learning method by the machine learning apparatus 5B is the same as that of the second embodiment (FIG. 19), description thereof is omitted.

The evaluation index influence part 306 inputs the substrate recipe information 11 and the transfer time information 12 acquired by the information acquisition part 300 to the learning model 16B, thereby inferring the evaluation index 14 of the substrate processing schedule 13 with respect to the substrate recipe information 11 and the transfer time information 12.

(Information Processing Method)

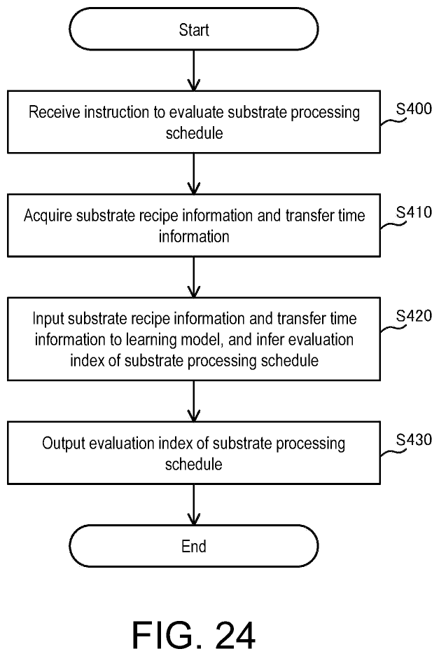

FIG. 24 is a flowchart illustrating an example of an information processing method performed by the information processing apparatus 3C according to the third embodiment.

First, in step S400, the user gives an instruction to start evaluating the substrate processing schedule 13. Thereupon, in step S410, the information acquisition part 300 acquires the substrate recipe information 11 and the transfer time information 12.

Next, in step S420, based on the output data output from the learning model 16B by input of the substrate recipe information 11 and the transfer time information 12 acquired in step S410 to the learning model 16B as input data, the evaluation index influence part 306 infers the evaluation index 14 of the substrate processing schedule 13 with respect to the substrate recipe information 11 and the transfer time information 12.

Next, in step S430, the output processing part 303 performs output processing for outputting the evaluation index 14 of the substrate processing schedule 13 inferred in step S420, and the series of steps of the information processing method illustrated in FIG. 24 are ended. In the above information processing method, step S410 corresponds to the information acquisition process, step S420 corresponds to an evaluation index inference process, and step S430 corresponds to the output processing process.

As described above, according to the information processing apparatus 3C and the information processing method according to the present embodiment, the evaluation index influence part 306 is able to calculate the evaluation index 14 of the substrate processing schedule 13 by inputting the substrate recipe information 11 and the transfer time information 12 to the learning model 16B.

### Other Embodiments

The disclosure is not limited to the above embodiments, and various modifications can be made without departing from the gist of the disclosure. All of the modifications are contained in the technical idea of the disclosure.

In the above embodiments, the substrate processing apparatus 2 and the information processing apparatuses 3A to 3C are described as being configured as separate apparatuses. However, they may be configured as a single apparatus. For example, the information processing apparatuses 3A to 3C may be incorporated in the control unit 25 of the substrate processing apparatus 2. The machine learning apparatuses 5A and 5B may also be incorporated in the control unit 25 of the substrate processing apparatus 2.

In the above embodiments, the substrate processing apparatus 2 is described as performing chemical mechanical polishing processing as polishing processing. However, the substrate processing apparatus 2 may perform physical mechanical polishing instead of chemical mechanical polishing.

In the above embodiments, a case is described where the substrate processing apparatus 2 includes each processing unit (polishing unit, finishing unit, and transfer unit), as illustrated in FIG. 2. However, as the configuration of each processing unit, the number of processings, arrangement, relationship between upstream and downstream, parallel relationship and serial relationship are not limited to the example of FIG. 2 and may be changed as appropriate. For example, the number of polishing units may be 3 or more. By providing a plurality of polishing processing transporters 240 or a plurality of finishing processing transporters 241 as transfer units, transfer processing may be performed in parallel. By providing a plurality of sets each defined by the first to third finishing units 23A to 23C, finishing processing may be performed in parallel. The position where the wafer W is delivered between each processing unit or the position where the wafer W is temporarily put on standby or the like may be changed as appropriate, or the number thereof may be added as appropriate. In such a case, the constraint, objective function and decision variable for mathematical optimization in the mathematical optimization part 301B may be changed according to the configuration of each processing unit. A data configuration of the learning data 15A, 15B as well as the input data and output data in the learning models 16A and 16B may be changed according to the configuration of each processing unit.

In the above embodiments, a case is described where a neural network is employed as a learning model realizing machine learning by the machine learning parts 305A and 305B. However, other machine learning models may be employed. Examples of the other machine learning models include: a tree type, such as a decision tree and a regression tree; ensemble learning, such as bagging and boosting; a neural network type (including deep learning), such as a recurrent neural network, a convolutional neural network, and a long short-term memory (LSTM) network; a clustering type, such as hierarchical clustering, non-hierarchical clustering, k-nearest neighbor clustering, and k-means clustering; multivariate analysis, such as principal component analysis, factor analysis, and logistic regression; and support vector machines. A machine learning algorithm according to the machine learning parts 305A and 305B may employ reinforcement learning instead of supervised learning.

(Machine Learning Program and Information Processing Program)

The disclosure may also be provided in the form of a program (information processing program) for functioning the computer 900 as each part provided in the information processing apparatuses 3A to 3C or a program (information processing program) for causing the computer 900 to execute each process included in the information processing method according to the above embodiments. The disclosure may also be provided in the form of a program (machine learning program) that causes the computer 900 to function as each part provided in the machine learning apparatuses 5A and 5B, or a program (machine learning program) for causing the computer 900 to execute each process included in a machine learning method.

1. An information processing apparatus, creating a substrate processing schedule for sequentially performing each processing on a predetermined number of substrates in a substrate processing apparatus comprising a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate, wherein the information processing apparatus comprises:
an information acquisition part, acquiring recipe information and transfer time information, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position; and
a schedule creation part, based on the recipe information and the transfer time information acquired by the information acquisition part, creating the substrate processing schedule by determining a start timing of each of the processing so that a final processing end time during which a last one of the substrate after the finishing processing is carried out to the substrate carry-out position is shortest.

2. The information processing apparatus according to claim 1, wherein the schedule creation part comprises:
a processing time calculator, based on the recipe information, calculating a polishing time required for the polishing processing and a finishing time required for the finishing processing; and
a mathematical optimization part, creating the substrate processing schedule by performing mathematical optimization in which the start timing of each of the processing is determined with a processing order condition that defines an order of performing each of the processing and a simultaneous processing condition that defines which of the processings are able or unable to be simultaneously performed as a constraint for the mathematical optimization, and with minimizing the final processing end time as an objective function for the mathematical optimization that comprises the polishing time and the finishing time calculated by the processing time calculator and the transfer time indicated in the transfer time information as a variable.

3. The information processing apparatus according to claim 2, wherein
the mathematical optimization part performs the mathematical optimization further with a post-polishing finishing start range condition that defines a range of a post-polishing finishing start time from an end timing of the polishing processing to the start timing of the finishing processing in the most upstream process as the constraint.

4. The information processing apparatus according to claim 3, wherein
the mathematical optimization part performs the mathematical optimization further with minimizing a total value, an average value or a maximum value of the post-polishing finishing start time as the objective function.

5. The information processing apparatus according to claim 1, wherein the schedule creation part comprises:
a schedule inference part, creating the substrate processing schedule with respect to the recipe information and the transfer time information acquired by the information acquisition part by inputting the recipe information and the transfer time information to a learning model that has learned by machine learning a correlation between the recipe information and the transfer time information and the substrate processing schedule for sequentially performing the polishing processing and the finishing processing based on the recipe information as well as the transfer processing requiring the transfer time indicated in the transfer time information on the number of the substrates.

6. The information processing apparatus according to claim 1, further comprising:
a schedule evaluation part, evaluating the substrate processing schedule created by the schedule creation part, and calculating an evaluation index of the substrate processing schedule as an evaluation result, wherein
the evaluation index comprises at least one of:
number of the substrates processed per unit time;
takt time of each of the processing;
rate-determining processing among the processings that requires a longest processing time; and
degree of variation in a post-polishing finishing start time from an end timing of the polishing processing to the start timing of the finishing processing in the most upstream process.

7. An information processing apparatus, evaluating a substrate processing schedule for sequentially performing each processing on a predetermined number of substrates in a substrate processing apparatus comprising a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate, wherein the information processing apparatus comprises:
an information acquisition part, acquiring recipe information and transfer time information, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position; and
an evaluation index inference part, inferring an evaluation index with respect to the recipe information and the transfer time information acquired by the information acquisition part by inputting the recipe information and the transfer time information to a learning model that has learned by machine learning a correlation between the recipe information and the transfer time information and the evaluation index when evaluating the substrate processing schedule for sequentially performing the polishing processing and the finishing processing based on the recipe information as well as the transfer processing requiring the transfer time indicated in the transfer time information on the number of the substrates.

8. A machine learning apparatus, generating a learning model for creating a substrate processing schedule for sequentially performing each processing on a predetermined number of substrates in a substrate processing apparatus comprising a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate, wherein the machine learning apparatus comprises:
a learning data storage part, storing a plurality of sets of learning data configured in which recipe information and transfer time information are input data, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position, and the substrate processing schedule for sequentially performing the polishing processing and the finishing processing based on the recipe information as well as the transfer processing requiring the transfer time indicated in the transfer time information on the number of the substrates is output data;
a machine learning part, causing the learning model to learn a correlation between the input data and the output data by inputting the plurality of sets of learning data to the learning model; and
a learned model storage part, storing the learning model that has learned the correlation by the machine learning part.

9. A machine learning apparatus, generating a learning model for evaluating a substrate processing schedule for sequentially performing each processing on a predetermined number of substrates in a substrate processing apparatus comprising a plurality of polishing units that perform polishing processing on the substrate in parallel, a plurality of finishing units that perform finishing processing on the substrate after the polishing processing in order of finishing processes, and a plurality of transfer units that perform transfer processing for transferring the substrate, wherein the machine learning apparatus comprises:
a learning data storage part, storing a plurality of sets of learning data configured in which recipe information and transfer time information are input data, the recipe information indicating processing content of the polishing processing and the finishing processing, the transfer time information indicating a transfer time required for each of following processing as the transfer processing: carry-in processing for carrying the substrate from a substrate carry-in position into a first substrate delivery position, pre-polishing transfer processing for transferring the substrate from the first substrate delivery position to the plurality of polishing units, post-polishing transfer processing for transferring the substrate after the polishing processing from the plurality of polishing units to a second substrate delivery position, pre-finishing transfer processing for transferring the substrate after the polishing processing from the second substrate delivery position to the finishing unit in a most upstream process, in-finishing transfer processing for transferring the substrate in the middle of the finishing processing between the plurality of finishing units in the order of finishing processes, and carry-out processing for carrying out the substrate after the finishing processing from the finishing unit of a most downstream process to a substrate carry-out position, and an evaluation index when evaluating the substrate processing schedule for sequentially performing the polishing processing and the finishing processing based on the recipe information as well as the transfer processing requiring the transfer time indicated in the transfer time information on the number of the substrates is output data;
a machine learning part, causing the learning model to learn a correlation between the input data and the output data by inputting the plurality of sets of learning data to the learning model; and
a learned model storage part, storing the learning model that has learned the correlation by the machine learning part.
